(19) United States
(12) Patent Application Publication
(10) Pub. No.: US 2015/0264802 A1
(43) Pub. Date: Sep. 17, 2015

(54) ELECTRICAL DEVICE AND ELECTRICAL COMPRESSOR

(71) Applicant: VALEO SYSTEMES DE CONTROLE MOTEUR, Cergy Saint Christophe (FR)

(72) Inventors: Hubert Lescot, Eragny (FR); Yoann Legendre, Pontoise (FR)

(73) Assignee: Valeo Systemes de Controle Moteur, Cergy Saint Christophe (FR)

(21) Appl. No.: 14/426,876

(22) PCT Filed: Jul. 29, 2013
(86) PCT No.: PCT/FR2013/051828

§ 371 Date: Mar. 9, 2015

(30) Foreign Application Priority Data
Sep. 10, 2012 (FR) 1258431

(51) Int. Cl. H05K 1/02; H05K 5/04

(52) U.S. Cl. CPC H05K 1/0215; H05K 5/04

(57) ABSTRACT

An electrical device and electrical compressor. The electrical device (102) comprises an electrical circuit (104) comprising a metal substrate (202), a layer of dielectric material (206) extending over the metal substrate (202), and a metal strip (208) extending over the layer of dielectric material (206). It further comprises a linking conductive part (218) intended to be connected to an electrical ground (106) and having a first contact end (220) intended to be pressed against the metal strip (208), and a pushing device (224) intended to take a first position, called the closed position, in which the pushing device (224) presses against a support portion (226) of the linking conductive part (218) so as to press the first contact end (220) against the metal strip (208), the support portion (226) being located away from the first contact end (220), and a second position, called the open position, in which the pushing device (224) allows the first contact end (220) to be separated from the metal strip (208).

The present invention relates to an electrical device and an electrical compressor.

FIG. 3 shows an electrical device of the prior art comprising a casing 2 forming an electrical ground and supporting an electrical circuit 4. The electrical circuit 4 comprises a metal substrate 6, a layer of dielectric material 8 extending over the entire upper face of the metal substrate 6, and metal tracks, such as the track 10 shown, extending over the layer of dielectric material 8.

Electrical components, such as the component 12 shown, are electrically connected to the tracks so as to be electrically connected to each other in order to perform a desired function.

In order to ensure filtering of the common mode current (illustrated by a dotted line), the electrical device furthermore comprises a capacitor 14, for example a capacitor of class Y, having a terminal connected to the metal track 10 and a terminal connected to the casing 2. A busbar 16 connects a terminal of the capacitor 14 to the track 10, while another busbar 18 connects another terminal of the capacitor 14 to the casing 2. The busbars 16, 18 are generally screwed to the elements they connect.

These busbars have the disadvantage of being complex and necessitating specific assembly operations to put them in place.

The need has therefore appeared for a new type of electrical circuit allowing a terminal of an electrical component to be connected to the metal substrate of an electrical circuit without using a busbar.

In order to achieve this objective, the invention relates to an electrical device comprising an electrical circuit comprising a metal substrate, a layer of dielectric material extending over the metal substrate and a metal track extending over the layer of dielectric material, characterized in that it furthermore comprises a linking conductive part intended to be connected to an electrical ground and having a first contact end intended to be pressed against the metal track, and a pushing device intended to take, on one hand, a first position, called the closed position, in which the pushing device presses against a support portion of the linking conductive part so as to press the first contact end against the metal track, the support portion being located away from the first contact end, and, on the other hand, a second position, called the open position, in which the pushing device allows the first contact end to be separated from the metal track.

Thanks to the invention, it is possible to dispense with the busbar. The mechanical strength of the attachment of an electrical component intended to filter a common mode current is improved, since an attachment to a track is better than an attachment to a busbar. Furthermore, the absence of the busbar and the possibility of disconnecting the electrical circuit from the casing enable a larger space to be obtained for performing dielectric strength tests on the electrical circuit.

In an optional manner, the electrical device furthermore comprises a metal casing forming the electrical ground and forming a support for the electrical circuit.

In an optional manner, the electrical circuit is encased between the metal casing and the first contact end of the linking conductive part.

In an optional manner, the linking conductive part comprises a second contact end intended to be pressed against the metal casing, and the pushing device is intended, in its closed position, to press against the support portion so as to press the second contact end against the metal casing, and, in its open position, to allow the second contact end to be separated from the metal casing.

In an optional manner, the pushing device comprises a bolt screwed through the linking conductive part, the bolt having a head intended to press against the support portion of the conductive part and an end, opposite the head and intended to be fastened to the metal casing, said bolt being intended to be selectively screwed and unscrewed so as to pass from one position of the pushing device to the other.

In an optional manner, the metal casing is pierced by an opening, said opening comprising an insulating material into which the end of the bolt is configured to be screwed so as to be fastened to the metal casing.

In an optional manner, the electrical circuit furthermore comprises en electrical component having a first terminal connected to the metal track by material fusion.

In an optional manner, the terminals of the electrical component are connected by brazing.

In an optional manner, the electrical component is a capacitor intended to perform a filtering of a common mode current in said circuit.

In an optional manner, the casing includes at least one rim intended to come opposite at least one peripheral edge of the circuit, the linking part providing the link to the electrical ground by coming to press against the rim of the casing and against the electrical circuit, notably against the peripheral edge, and/or, in particular, straddling a space between the rim and the peripheral edge of the circuit.

The invention also relates to an electrical compressor comprising an electrical device according to the invention, wherein the electrical device is an inverter.

Of course, the different variants and embodiment forms of the invention can be associated one with the other in various combinations, provided that they are not incompatible or exclusive one from the other.

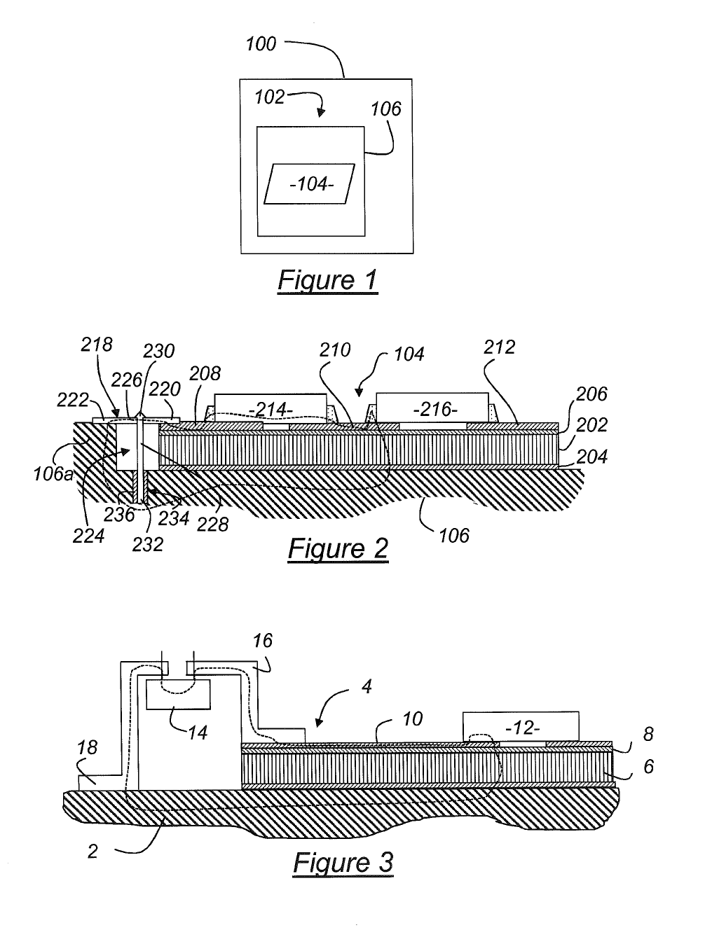

Furthermore, various other characteristics of the invention emerge from the attached description made with reference to FIGS. 1 and 2, which illustrate a non-limitative embodiment of an electrical compressor according to the invention.

FIG. 1 is a simplified view of an electrical compressor according to the invention;

FIG. 2 is a sectional view, from the side, of a casing and an electrical circuit of the electrical compressor of FIG. 1;

FIG. 3, already described, is a sectional view, from the side, of a casing and an electrical circuit according to the prior art.

With reference to FIGS. 1 and 2, an electrical compressor 100 according to the invention will now be described.

With reference to FIG. 1, the electrical compressor 100 comprises in particular an inverter 102, whose function is to deliver a voltage and/or an alternating current from a source of direct electrical energy.

The inverter 102 comprises an electrical circuit 104 intended to perform, at least in part, the function of an inverter, and a metal casing 106 enclosing the circuit 104. The casing 106 forms an electrical ground. Furthermore, in the example described, the casing 106 forms a plane support for the circuit 104.

With reference to FIG. 2, the electrical circuit 104 comprises first of all a metal substrate 202, electrically connected to the casing 106. In the example described, the substrate 202 is in the form of a board having a lower face pressed against the casing 106. The substrate 202 is, for example, a layer of aluminum.

In the example described, the circuit 104 furthermore comprises heat conductive grease 204 interposed between the casing 106 and the substrate 202 so as to ensure heat conduction between the two and thus to dissipate the heat released by the circuit 104 into the casing 106. The grease 204 nevertheless allows electrical conduction between the substrate 202 and the casing 106 so as to provide electrical conduction between the casing 106 and the substrate 202 through the lower face of the latter.

The circuit 104 furthermore comprises a layer of dielectric material 206 extending over a first part of the substrate 202, on an upper face of the latter. The dielectric material is, for example, ceramic.

The electrical circuit 104 furthermore comprises metal tracks, such as the tracks 208, 210 and 212 shown, extending over the layer of dielectric material 206. In the example described, the tracks are in copper.

An electrical circuit such as the circuit 104 is often designated by the acronym IMS meaning “Insulated Metal Substrate”.

The circuit 104 furthermore comprises electrical components such as the components 214 and 216 shown, electrically connected to the tracks so as to be electrically connected to each other, in order to perform, at least in part, the function of an inverter. The components are connected to the tracks by material fusion, by brazing in the example described. The electrical component 214 thus has a first terminal connected by material fusion to the metal track 208, and a second terminal connected by material fusion to the track 210. Likewise, the electrical component 216 has a first terminal connected by material fusion to the metal track 210, and a second terminal connected by material fusion to the track 212. In the example described, where brazing is used, these connections give rise to brazings shown as dots in the figure.

The component 214 is intended to be connected to the electrical ground comprising, in the example described, the casing 106. In the example described, the electrical component 212 is a capacitor, for example, a capacitor of class Y, known in the art.

In order to bring the track 208 to the electrical ground, the inverter 102 furthermore comprises a linking conductive part 218 intended to connect the track 208 to the electrical ground, formed, in the example described, by the casing 106. The linking conductive part 218 is, for example, in metal. In the example described, the linking conductive part 218 has a first contact end 220 intended to be pressed movably against the track 208 and a second contact end 222 intended to be pressed movably against the casing 106.

The inverter 102 furthermore comprises a pushing device 224 intended selectively to take a first position, called the closed position, and a second position, called the open position. In the closed position, the pushing device 224 is intended to press against a support portion 226 of the linking conductive part 218 so as to press the latter against the track 208, and to press the second contact end 222 against the casing 106. The support portion 226 is located away from the first contact end 220 and from the second contact end 222. In the open position, the pushing device 224 is intended to release the pressure against the support portion 226 so as to allow the first contact end 220 to be separated from the metal track 208, and the second contact end 220 to be separated from the metal casing 106.

In the example described, the pushing device 224 comprises a bolt 228 screwed through the portion 226 of the linking conductive part 218, and having a head 230 intended to press against the portion 226. The bolt 228 furthermore has an end 232, opposite the head 230 and fastened to the casing 106. The bolt 228 is intended to be screwed to place the pushing device 224 in the closed position. In this case, the head 230 presses against the support portion 226 of the linking conductive part 218. The bolt 228 is furthermore intended to be unscrewed, for example, until withdrawn, so as to place the pushing device 224 in the open position. In this case, the head 230 no longer presses against the support portion 226 and the linking conductive part 218 can be withdrawn.

In the example described, the casing 106 is pierced with an opening 234, and the inverter 102 furthermore comprises an insulating plug 236 inserted in the opening 234. The end 232 of the bolt 228 is thus intended to be screwed into the insulating plug 236 so as to be fastened to the casing 106. By this method, no common mode current passes into the bolt, between the linking conductive part 218 and the casing 106.

Also preferably, the metal track 208 and the casing 106 each have a surface treated so as to facilitate electrical conductivity, respectively with the first contact end 220 and the second contact end 222.

It will be appreciated that the electrical circuit is encased between the casing 106 and the first contact end 220 of the linking conductive part 218. The linking conductive part 218 and the pushing device 224 thus hold the circuit 104 in place against the casing and thus ensure the mechanical stability of the circuit 104.

As the component 214 is connected to the tracks 208, 210 by material fusion, it can be assembled at the same time as the other components, like the component 216, in a single oven charge. Qualification tests of the components of the circuit 104 can then be conducted without making the ground connection, which is often necessary for these tests. The linking conductive part 218 is only added and held in place by the pushing device 224 in a third step. It will be appreciated that this third step does not necessitate returning the circuit 104 to the oven.

Furthermore, the common mode current emerging from the component 216, shown as a dotted line in FIG. 2, passes into the track 210, then through the component 214, then into the track 208, into the linking conductive part 218, into the casing 106, into the metal substrate 202, then returns to the component 216 through the layer of dielectric material 206.

The invention is not limited to the embodiment described above with reference to FIGS. 1 and 2, but on the contrary, is defined by the claims that follow. In particular, the terms used in the claims are not limited to the examples given in the described embodiment.

For example, as a variant, brazing could be replaced by soldering.

In particular, since the support portion 226 of the linking conductive part 218 is located away from the first contact end 220, it is no longer necessary to pass through the electrical circuit 104 to press the first contact end 220 against the metal track 208. Pressure of the linking part 218 against the electrical circuit 104 can thus be obtained without passing through the electrical circuit 104. It is therefore not necessary to provide a dimension between a through hole and an edge of the electrical circuit 104, which improves the integration density of the circuit 104. Notably, the pushing device 224 presses against the support portion 226 of the linking conductive part 218 without passing through the circuit 104.

In an embodiment compatible with those described above, the casing 106 comprises at least one rim 106a intended to come opposite at least one peripheral edge of the circuit 104. The linking part 218 thus provides the connection to the electrical ground by straddling a space between the rim 106a and the peripheral edge of the circuit 104. In particular, the pushing device 224 is intended to press against the linking part 218 by passing a rod, for example the bolt 228, between the rim 106a of the casing and the peripheral edge of the circuit 104.

Notably, no common mode current passes into the pushing device 224, or a very weak portion. Any uncertainty about the impedance of the path traveled by the current is avoided by making the connection to the electrical ground through the linking part 218 instead of a threaded part. In fact, electrical conduction through a threaded part is difficult to control.

1. An electrical device comprising:
an electrical circuit comprising:
a metal substrate,
a layer of dielectric material extending over the metal substrate, and
a metal track extending over the layer of dielectric material;
a linking conductive part configured to connect to an electrical ground and having a first contact end being pressed against the metal track; and
a pushing device configured to take:
a first closed position in which the pushing device presses against a support portion of the linking conductive part so as to press the first contact end against the metal track, the support portion being located away from the first contact end, and
a second open position in which the pushing device allows the first contact end to be separated from the metal track.

2. The electrical device as claimed in claim 1, further comprising a metal casing forming the electrical ground and forming a support for the electrical circuit.

3. The electrical device as claimed in claim 2, wherein the electrical circuit is encased between the metal casing and the first contact end of the linking conductive part.

4. The electrical device as claimed in claim 2, wherein the linking conductive part comprises a second contact end configured to be pressed against the metal casing, and wherein the pushing device, in the first closed position, presses against the support portion so as to press the second contact end against the metal casing, and, in the second open position, to allow the second contact end to be separated from the metal casing.

5. The electrical device as claimed in claim 2, wherein the pushing device comprises a bolt screwed through the linking conductive part, the bolt having a head intended to press against the support portion of the conductive part and an end opposite the head, and intended to be fastened to the metal casing, said bolt being selectively screwed and unscrewed so as to pass from one position of the pushing device to the other.

6. The electrical device as claimed in claim 5, wherein the metal casing is pierced by an opening, said opening comprising an insulating material into which the end of the bolt is configured to be screwed so as to be fastened to the metal casing.

7. The electrical device as claimed in claim 1, wherein the electrical circuit further comprises an electrical component having a first terminal connected to the metal track by material fusion.

8. The electrical device as claimed in claim 7, wherein the electrical component is a capacitor intended to perform a filtering of a common mode current in said circuit.

9. The electrical device as claimed in claim 2, wherein the casing includes at least one rim opposite at least one peripheral edge of the circuit, the part providing the link to the electrical ground by coming to press against the rim of the casing and against the electrical circuit.

10. An electrical compressor comprising an electrical device as claimed in claim 1, wherein the electrical device is an inverter.
